(19) United States
(12) Patent Application Publication
(10) Pub. No.: US 2014/0367634 A1
(43) Pub. Date: Dec. 18, 2014

(54) NITRIDE-BASED LIGHT EMITTING DIODE INCLUDING NONORODS AND METHOD OF MMANUFACTURING THE SAME

(71) Applicant: GWANGJU INSTITUTE OF SCIENCE AND TECHNOLOGY, Gwangju (KR)

(72) Inventors: Dong-Seon LEE, Gwangju (KR); Dukjo KONG, Gwangju (KR); Si Young BAE, Gwangju (KR)

(73) Assignee: GWANGJU INSTITUTE OF SCIENCE AND TECHNOLOGY, Gwangju (KR)

(21) Appl. No.: 14/080,964

(22) Filed: Nov. 15, 2013

(30) Foreign Application Priority Data
Jun. 12, 2013 (KR) 10-2013-0067099

(51) Int. Cl. H01L 33/24; H01L 33/00; H01L 33/06

(52) U.S. Cl. CPC H01L 33/24; H01L 33/06; H01L 33/0075
USPC 257/13; 438/22

(57) ABSTRACT

Disclosed are a nitride-based light emitting diode (LED) and a method of manufacturing the same. The LED includes an n-type nitride semiconductor layer formed on a substrate, a plurality of n-type nitride semiconductor nanorods formed on the n-type nitride semiconductor layer and each having a non-polar face on a major surface thereof, a photoactive layer formed on the n-type nitride semiconductor layer and surfaces of the n-type nitride semiconductor nanorods, a p-type nitride semiconductor layer formed in a hexagonal pyramid shape on the photoactive layer, a current spreading layer formed on the p-type nitride semiconductor layer, an anode formed on the current spreading layer, and a cathode formed on an exposed surface of the n-type nitride semiconductor layer.

### CROSS-REFERENCE TO RELATED APPLICATION

This application claims priority to Korean Patent Application No. 10-2013-0067099 filed on 12 Jun. 2013, and all the benefits accruing therefrom under 35 U.S.C. §119, the contents of which is incorporated by reference in its entirety.

### BACKGROUND

1. Technical Field

The present invention relates to a light emitting diode and, more particularly, to a nitride-based light emitting diode including nanorods and a method of manufacturing the same.

2. Description of the Related Art

Light emitting diodes (LEDs) are single-wavelength light sources which are used in applications as diverse as automotive lighting, electronic display, general lighting, and lighting for backlight units of displays. An LED include an n-type semiconductor layer, a p-type semiconductor layer, and an active layer between the n-type and p-type semiconductor layers, and operate such that, when forward electric field is applied to the n-type and p-type semiconductor layers, electrons and holes are injected into the active layer and recombine, thereby emitting light.

As materials for LEDs, group III-V compounds such as GaN and the like have a wide energy band gap and a direct transition type band structure, and are expected to be used in applications of blue or ultraviolet LEDs due to both a wide adjustable bandwidth ranging from ultraviolet to near infrared depending upon a composition ratio of Al, Ga and In, and excellent physical/chemical properties. Such group III-V compounds are increasingly used in electronic devices applicable to high temperature and high frequency applications due to high thermal conductivity and high temperature stability thereof as well as excellent optical properties.

Research into improving the performance of an LED has recently been conducted by, for example, developing a blue LED in an InGaN active layer using c-axis polar substrate depending upon configuration and modification of a nitride thin film with MOCVD. However, in the case of a typically used c-axis grown polar thin film, electrons and holes in an active layer are caused to decouple by spontaneous polarization occurring due to different atom arrangement of Ga atoms and N atoms. Decoupling of electrons and holes shortens light-emitting lifetime, causes red shift in an LED, and greatly reduces internal quantum efficiency in producing photons. Accordingly, there is a need for a method of reducing piezoelectric field in order to fabricate a high power, high brightness LED.

### BRIEF SUMMARY

Therefore, the present invention has been conceived to solve such problems in the related art, and the present invention is aimed at providing a nitride-based light emitting diode including nanorods to improve light-emitting performance, which can be reduced due to a c-axis grown polar thin film, and a method of manufacturing the same.

The present invention is also aimed at provide a nitride-based light emitting diode including nanorods to improve internal quantum efficiency so as to obtain high power and high brightness, and a method of manufacturing the same.

An aspect of the present invention is to provide a nitride-based light emitting diode (LED) including nanorods.

The nitride-based LED includes: an n-type nitride semiconductor layer formed on a substrate; a plurality of n-type nitride semiconductor nanorods formed on the n-type nitride semiconductor layer and each having a non-polar face on a major surface thereof; a photoactive layer formed on the n-type nitride semiconductor layer and surfaces of the n-type nitride semiconductor nanorods; a p-type nitride semiconductor layer formed in a hexagonal pyramid shape on the photoactive layer; a current spreading layer formed on the p-type nitride semiconductor layer; an anode formed on the current spreading layer; and a cathode formed on an exposed surface of the n-type nitride semiconductor layer.

The n-type nitride semiconductor layer may have a diameter ranging from 200 nm to 2000 nm, the n-type nitride semiconductor layer, the p-type nitride semiconductor layer, or the photoactive layer may include GaN, and the photoactive layer may include a multi-quantum well structure depending upon indium content.

The n-type nitride semiconductor layer may have the same chemical composition as the n-type nitride semiconductor nanorods.

Another aspect of the present invention is to provide a method of manufacturing a nitride-based light emitting diode (LED) including nanorods.

The method includes: sequentially forming an n-type nitride semiconductor layer and a mask layer on a substrate; patterning the mask layer to expose a portion of a surface of the n-type nitride semiconductor layer to form an n-type nitride semiconductor protruding from the n-type nitride semiconductor layer; removing the mask layer; forming a plurality of nanorods having a non-polar face by removing a semi-polar face of the protruded n-type nitride semiconductor layer; forming a photoactive layer on the n-type nitride semiconductor layer and surfaces of the n-type nitride semiconductor nanorods; forming a p-type nitride semiconductor layer, protruding in a hexagonal pyramid shape, on the photoactive layer through intentional partial combination; forming a current spreading layer on the p-type nitride semiconductor layer; forming an anode on the current spreading layer; and forming a cathode on an exposed surface of the n-type nitride semiconductor layer.

The mask layer may include at least one selected from the group consisting of a silicon oxide film and a silicon nitride film; the nanorods may be formed by wet etching; wet etching may be performed using a KOH solution; and a concentration of KOH may range from 2 M to 4 M. Wet etching may be performed at a temperature ranging from 80° C. to 120° C. for 3 minutes to 20 minutes; and the photoactive layer may have a multi-quantum well structure depending upon indium content.

According to the present invention, the nitride-based LED and the method of manufacturing the same can improve the light emitting performance of an LED, which can be reduced due to a c-axis grown polar thin film, and improve internal quantum efficiency so as to obtain a high power and high brightness LED.

### BRIEF DESCRIPTION OF THE DRAWINGS

The above and other aspects, features, and advantages of the present invention will become apparent from the detailed description of the following embodiments in conjunction with the accompanying drawings, in which:

FIG. 1 is a sectional view of a light emitting diode (LED) according to one embodiment of the present invention;

FIGS. 2 to 9 are sectional views showing a method of manufacturing an LED according to one embodiment of the present invention;

FIG. 10 is a view including SEM photographs of a dry-etched nitride semiconductor according to one embodiment of the present invention;

FIGS. 11 to 15 are time-related SEM photographs showing a nitride semiconductor subjected to wet etching using a KOH solution after dry etching;

FIG. 16 is an SEM photograph showing formation of a pyramid-shaped p-type semiconductor layer according to one embodiment of the present invention; and

FIG. 17 is a graphical diagram showing optical properties of an LED according to one embodiment of the present invention.

### DETAILED DESCRIPTION

Hereinafter, embodiments of the present invention will be described in detail with reference to the accompanying drawings. It should be understood that the present invention is not limited to the following embodiments and may be embodied in different ways. Like components will be denoted by like reference numerals throughout the specification.

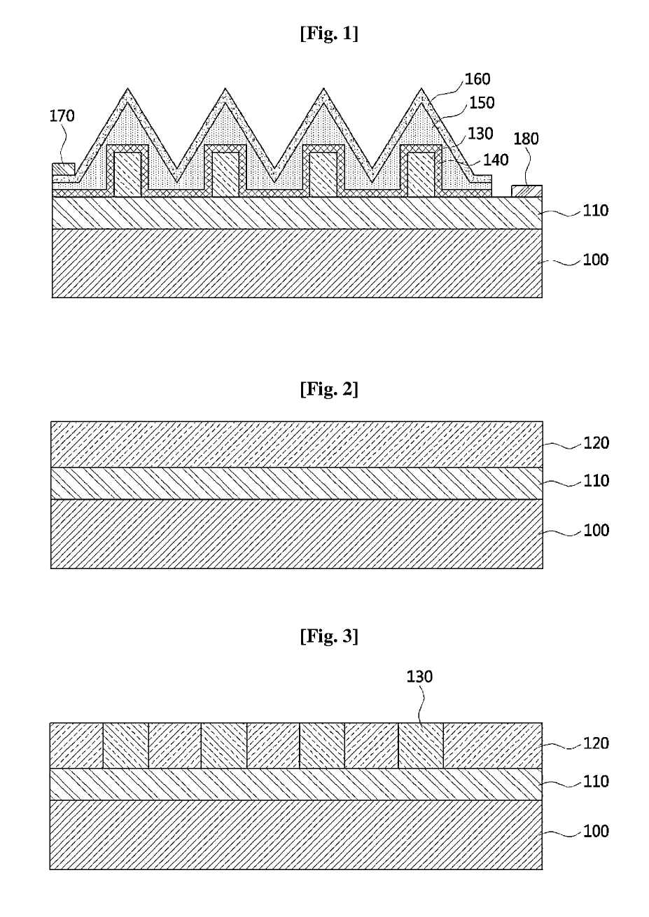

FIG. 1 is a sectional view of a light emitting diode (LED) according to one embodiment of the present invention.

A nitride-based LED including nanorods according to one embodiment of the invention includes an n-type nitride semiconductor layer 110 formed on a substrate 100, a plurality of n-type nitride semiconductor nanorods 130 formed on the n-type nitride semiconductor layer 100 and each having a non-polar face on a major surface thereof, a photoactive layer 140 formed on the n-type nitride semiconductor layer 110 and surfaces of the n-type nitride semiconductor nanorods 130, a p-type nitride semiconductor layer 150 formed in a hexagonal pyramid shape on the photoactive layer 140, a current spreading layer 160 formed on the p-type nitride semiconductor layer 150, an anode 170 formed on the current spreading layer 160, and a cathode 180 formed on an exposed surface of the n-type nitride semiconductor layer 110.

FIGS. 2 to 9 are sectional views showing a method of manufacturing an LED according to one embodiment of the present invention.

Referring to FIG. 2, an n-type nitride semiconductor layer 110 and a mask layer 120 are sequentially formed on a substrate 100.

The substrate 100 may have the same or similar crystal structure as that of the n-type nitride semiconductor layer 110 formed thereon. Thus, when the n-type nitride semiconductor layer 110 has a hexagonal system structure, the substrate 100 may also have a hexagonal system structure. Thus, the substrate 100 may include a sapphire substrate, without being limited to.

The n-type nitride semiconductor layer 110 is formed on the substrate 100. In order to have n-type conductivity, group-IV elements are used as dopants. Particularly, Si may be used as a dopant. The n-type nitride semiconductor layer 110 may be formed by MOCVD. The n-type nitride semiconductor layer 110 may be formed using a single crystal, and may be formed to have defects in some regions thereof. The n-type nitride semiconductor layer 110 is used as a carrier layer for electrons generated due to voltage.

The n-type nitride semiconductor layer 110 has a thickness ranging from 10 μm to 50 μm. If the thickness of the n-type nitride semiconductor layer 110 is less than 10 μm, it is difficult to secure sufficient crystallinity, and if the thickness of the n-type nitride semiconductor layer 110 exceeds 50 μm, an excessive processing time and loss in electron transport can occur.

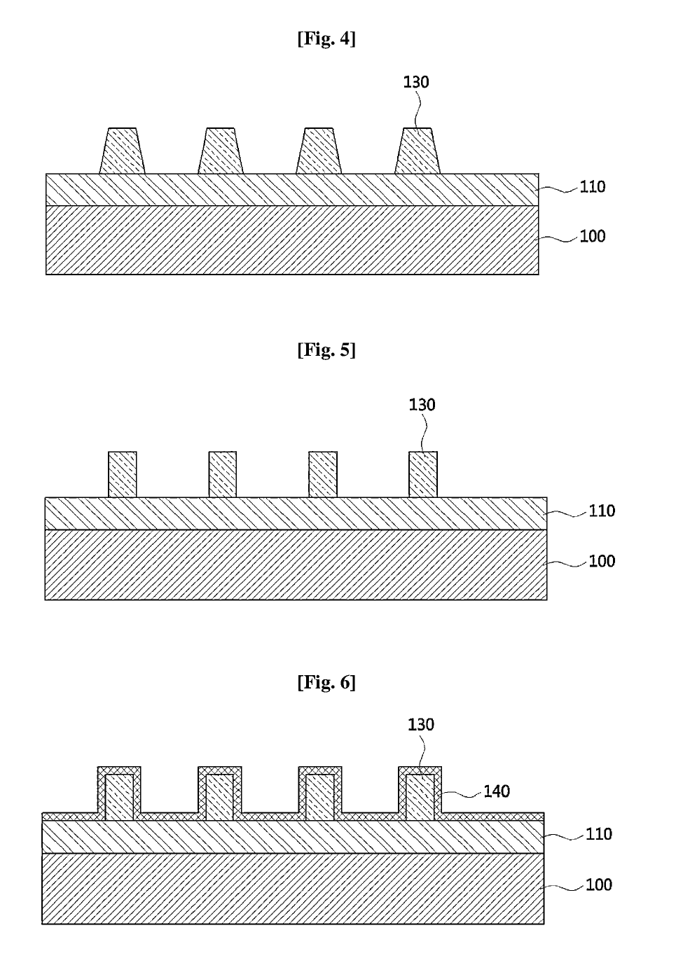

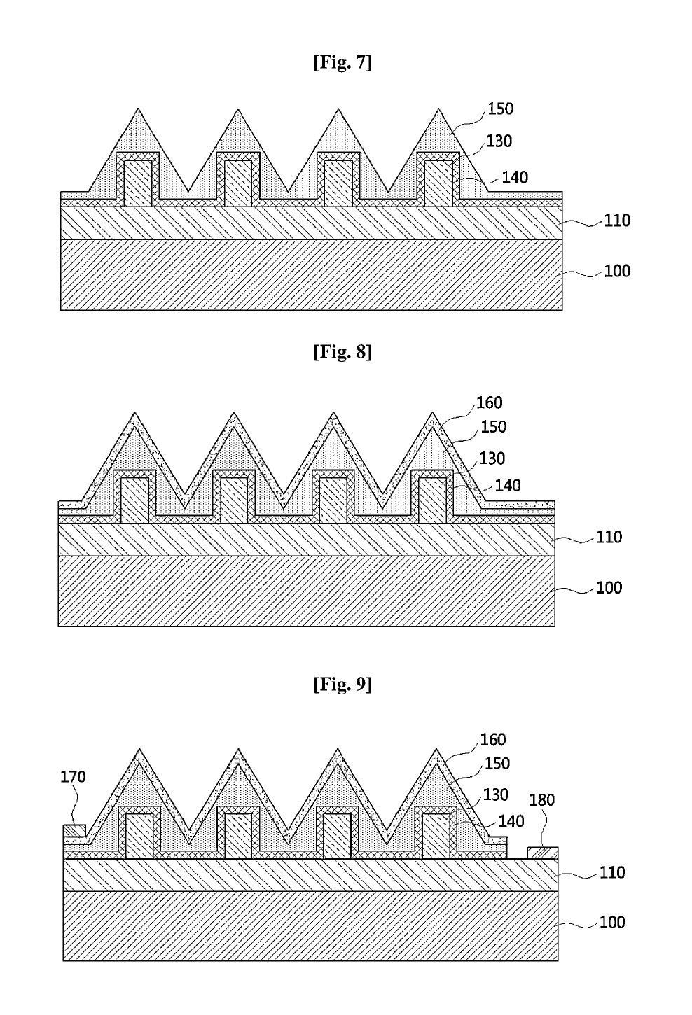

Referring to FIG. 3, the mask layer 120 is patterned to expose a portion of a surface of the n-type nitride semiconductor layer 110, thereby forming an n-type nitride semiconductor protruding from the n-type nitride semiconductor layer 110.

The mask layer 120 is formed on the n-type nitride semiconductor layer 110. The mask layer may be formed of any material so long as the material has etching selectivity with respect to the n-type nitride semiconductor layer 110 under an insulator. Here, the mask layer 120 may include at least one selected from the group including a silicon oxide film and a silicon nitride film. Silicon oxide may be used as the mask layer 120. This is because the silicon oxide film and the silicon nitride film facilitate formation of the mask layer 120 as these films are grown based on a film material thereunder. The mask layer 120 is formed by chemical vapor deposition or physical vapor deposition.

Next, the mask layer 120 is selectively etched to form a pattern having regular pitches. With the pattern formed, a portion of the n-type nitride semiconductor layer 110 is exposed. The exposed portion may be formed by typical photolithography and etching. That is, a photoresist layer is formed on the mask layer 120, and then is patterned to form a photoresist pattern. Next, etching is performed using the photoresist pattern as an etching mask, thereby forming a patterned mask layer. The pattern has a regular arrangement, and may have a width ranging from 300 nm to 5000 nm. The pattern may have a circular or rectangular shape. When the width of the pattern is less than 300 nm, it is difficult to improve operation efficiency of an LED because the n-type nitride semiconductor nanorods formed through the pattern do not have sufficient height. Further, when the width of the pattern exceeds 5000 nm, a sufficient number of the n-type nitride semiconductor nanorods cannot be formed on the substrate.

The formation of the pattern on the mask layer may be performed using a variety of methods, such as nano imprinting, laser interference lithography, holographic lithography, and the like.

An n-type nitride semiconductor is formed on the patterned structure. Here, the n-type nitride semiconductor protruding from the patterned structure has selectivity in growing a film. That is, the n-type nitride semiconductor is grown based on a film material having the same or similar crystal structure as that thereunder. Particularly, when the semiconductor is formed by chemical vapor deposition, growth of the n-type nitride semiconductor is determined depending upon a material under the n-type nitride semiconductor. For example, the n-type nitride semiconductor cannot be grown on the mask layer 120, such as silicon oxide, having an amorphous structure, and an n-type nitride semiconductor 130 protruding from open portion can be grown on the n-type nitride semiconductor 110.

Referring to FIG. 4, the mask layer 120 is removed.

With the mask layer 120 removed, when the photoactive layer 140 and the p-type nitride semiconductor layer are sequentially deposited on portions where the protruded n-type nitride semiconductor 130 is not grown, light can be emitted upon application of voltage, thereby improving light extraction efficiency.

The remaining mask layer 120 may be removed by chemical dry etching or wet etching.

Further, while the remaining mask layer 120 is removed, the protruded n-type nitride semiconductor can also be damaged, thereby forming a protruded n-type nitride having a semi-polar or polar face.

Referring to FIG. 5, a plurality of nanorods each having a non-polar face on a major surface thereof is formed.

Polarization due to arrangement and deformation of a nitride thin film is discontinuously present on a contact surface with an adjacent layer. Variation in polarization increases intensity of an internal electric field with combination with fixed charges. Accordingly, a c-axis generates a strong electric field at a heterogeneous interface due to piezoelectric polarization accompanied by spontaneous polarization and deformation. This phenomenon causes electrons and holes in an active layer to be separated. This separation of electrons and holes shortens light emitting lifetime, causes redshift in an LED, and greatly reduces internal quantum efficiency in generating photons.

To solve these problems, research has been conducted into use of a semi-polar or polar nitride semiconductor face. However, since such a semi-polar or polar nitride semiconductor has group-HI elements and nitrogen distributed in the same arrangement on a surface, electrical polarization does not occur. However, in the case of the nitride semiconductor vertically grown along the c-axis thereof, partial dislocations on opposite edges of a stacking-fault face are arranged perpendicular to the direction of the c-axis so that the partial dislocations do not face an upper layer therefrom. On the other hand, in the case of the semi-polar nitride semiconductor, partial dislocations generated due to basal stacking faults face an upper layer, thereby increasing fault density. Thus, the semi-polar nitride semiconductor has high fault density, thereby deteriorating light-emitting performance of an LED. Accordingly, when the semi-polar face of the nitride semiconductor is removed, performance of an LED can be enhanced.

Thus, the semi-polar face of the protruded n-type nitride semiconductor is removed by wet etching, thereby forming nanorods having non-polar faces on major surfaces thereof. Wet etching may be performed using an alkaline solution having a pH of 11 to 14. The alkaline solution may be a KOH or NaOH solution.

When wet etching is performed using a KOH solution, a concentration of KOH may range from 2 M to 4 M. When the concentration of KOH is less than 2 M, a wet etching rate can be slightly decreased, and when the concentration of KOH exceeds 5 M, the wet etching rate can be increased, but roughness of a surface to be etched can increase.

Wet etching may be performed at a temperature ranging from 80° C. to 120° C. for 3 minutes to 20 minutes. When the temperature is less than 80° C., the etching rate can be slightly decreased, and when the temperature exceeds 120° C., uniform etching cannot be performed due to rapid etching.

Through wet etching, the semi-polar face of the protruded n-type nitride semiconductor can be removed.

The n-type nitride semiconductor nanorods may have a diameter ranging from 200 nm to 2000 nm. As the diameter of the nanorods increases, crystallinity of the nanorods tends to decrease. Thus, the n-type nitride semiconductor nanorods preferably have a diameter ranging from 200 nm to 2000 nm.

The n-type nitride semiconductor may reduce output of totally internally reflected light, thereby improving light extraction efficiency.

Referring to FIG. 6, a photoactive layer 140 is formed on the n-type nitride semiconductor 110 and the surfaces of the n-type nitride semiconductor nanorods 130.

The photoactive layer 140 may have a quantum dot structure, an intrinsic semiconductor structure, or a multi-quantum well structure.

Particularly, when the photoactive layer has the multiple quantum-well structure, barrier layers and well layers are alternately formed. The barrier layer and the well layer are determined depending upon a composition ratio of indium. When the photoactive layer is formed in the multiple quantum-well structure, the barrier layer may have a thickness of 5 nm to 15 nm, and the well layer may have a thickness of 1.5 nm to 3.5 nm.

The photoactive layer 140 has the same crystal structure as those of the n-type nitride semiconductor layer 110 and the n-type nitride semiconductor nanorods 130, which are placed thereunder, and also has growth selectivity. For example, when the n-type nitride semiconductor layer 110 and the n-type nitride semiconductor nanorods 130 include GaN, the photoactive layer 140 may include InGaN. Here, as In content increases, it is possible to obtain an LED that emits a wide range of wavelengths of light.

Referring to FIG. 7, a p-type nitride semiconductor layer 150 is formed on the photoactive layer 140 in such a manner as to protrude in a hexagonal pyramid shape through intentional partial combination.

Group-II elements, such as Mg, may be used as a dopant for the p-type nitride semiconductor layer 150. Like the photoactive layer, the p-type nitride semiconductor layer has growth selectivity. Thus, the p-type nitride semiconductor layer is grown only on the photoactive layer. The p-type nitride semiconductor layer 150 may have a thickness ranging from 100 nm to 300 nm.

When the thickness of the p-type nitride semiconductor layer 150 is less than 100 nm, it is difficult to secure sufficient crystallinity, and when the thickness of p-type nitride semiconductor layer 150 exceeds 300 nm, holes have low mobility.

Referring to FIG. 8, a current spreading layer 160 is formed on the p-type nitride semiconductor layer 150.

The current spreading layer 160 needs to have a certain level of transmittance and electrical conductivity. Thus, ITO may be used for the current spreading layer. However, beside ITO, a variety of materials such as IZO may be used, as needed.

The current spreading layer 160 is deposited on the p-type nitride semiconductor layer 150 by a typical deposition process.

Referring to FIG. 9, the anode 170 and the cathode 180 are formed on the current spreading layer 160 and the exposed surface of the n-type nitride semiconductor layer 110, respectively.

The current spreading layer may be patterned by a typical photolithography process. Thus, the mask layer 120 is exposed in a certain region in which the cathode 180 is formed as shown in FIG. 1.

Next, the cathode 180 and the anode 170 are formed on the exposed surface of the n-type nitride semiconductor layer 110 and the current spreading layer, respectively. Formation of the cathode 180 and the anode 170 is carried out by a typical electrode-forming process using a mask. For example, the cathode may include Cr/Au or Ti/Al/Au. Further, the anode may include Cr/Au or Ni/Au.

Particularly, when forming an electrode pad, the cathode 180 and the anode 170 may be formed on a smooth surface of a film material thereunder. For example, the anode 170 and the cathode 180 may be formed on a smooth surface of the current spreading layer and a smooth surface of the N-type nitride semiconductor layer 110 exposed by etching.

Hereinafter, the present invention will be described in more detail with reference to a preferred example. However, it should be noted that this example is provided for illustration only and are not to be construed in any way as limiting the present invention.

Analysis of n-Type Nitride Nanorods According to Wet Etching Conditions

A Si-doped n-type GaN template was grown on a washed and dried sapphire substrate, followed by depositing SiO₂. A number of patterns each having a diameter of 500 nm to 2000 nm were formed via photolithography. After a GaN epitaxial layer was formed on patterned samples, the SiO₂ layer was removed via dry etching, thereby forming GaN nanorods. Next, wet etching was performed for 15 minutes on the samples using a boiling KOH solution having a concentration of 3 M.

For analysis of structural and optical features of the n-type nitride nanorods, scanning electron micrographs (SEMs), which were photographed at various angles, and measurement of intensity of photoluminescence (PL) were used. The PL value was measured using a He—Cd 325 laser at a resolution of 3 μm.

Further, for comparison, the features of GaN nanorods which were not wet-etched were also analyzed.

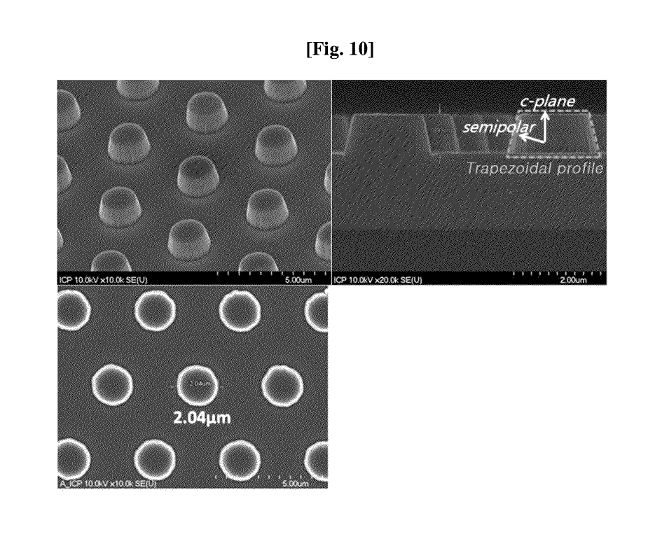

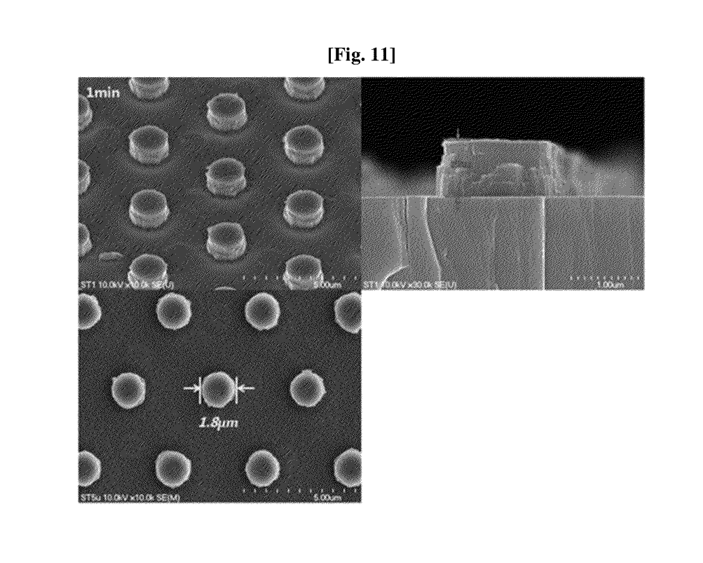

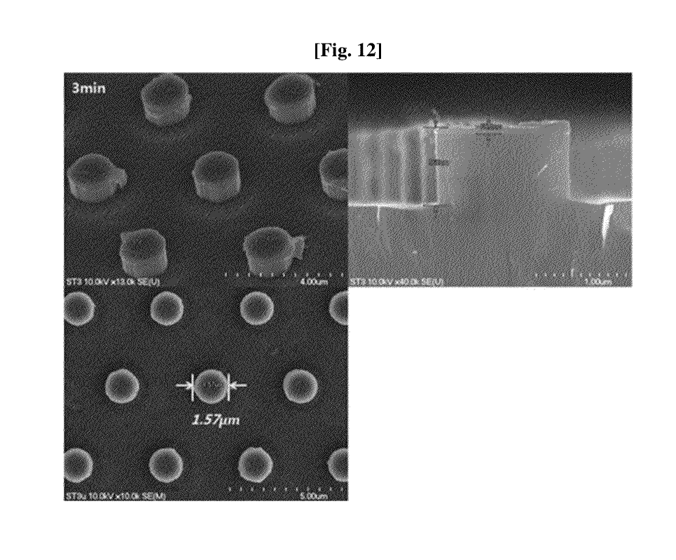

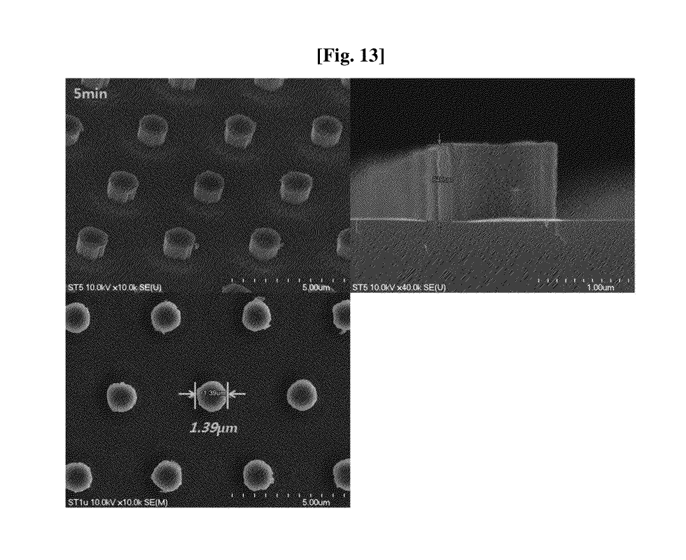

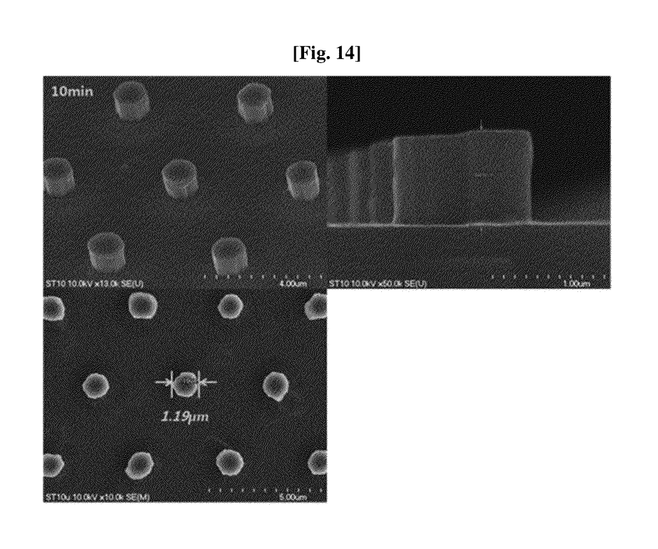

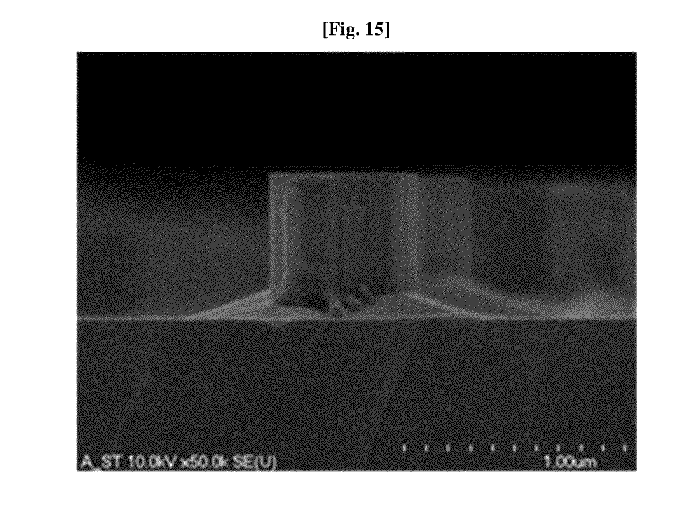

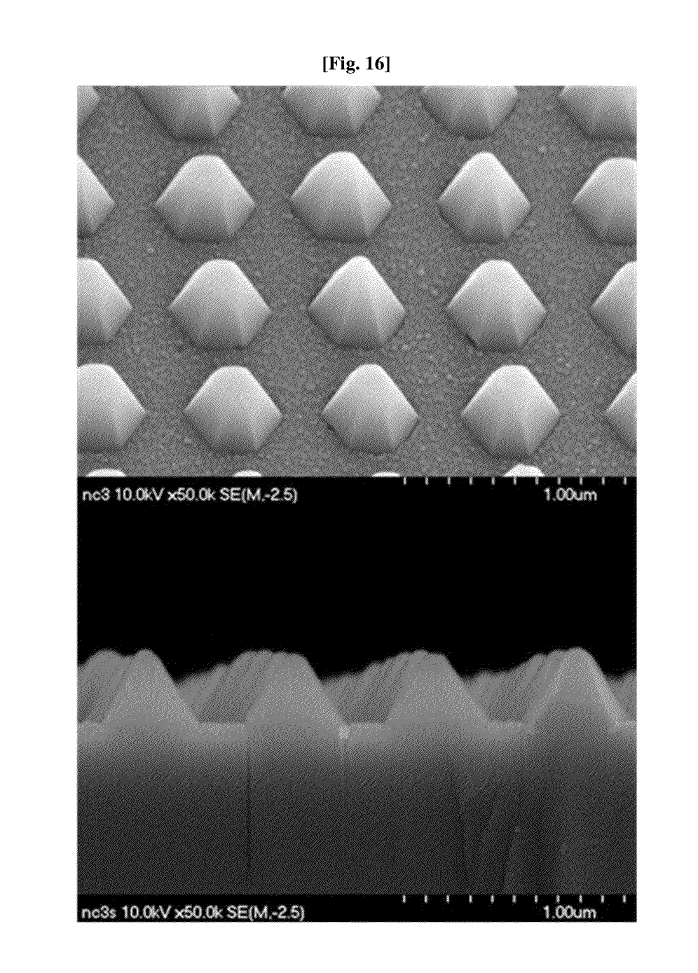

FIG. 10 is a view including SEMs of a dry-etched nitride semiconductor according to one embodiment of the invention, and FIGS. 11 to 15 are SEMs showing the states of the nitride semiconductor wet-etched using a KOH solution after dry etching when the etching time elapsed for 1 min, 3 min, 5 min, 10 min, and 15 min, respectively.

Referring to FIG. 10, in the case where the N-type nitride semiconductor was grown after the mask layer was formed, and the mask layer was dry-etched, the grown N-type nitride semiconductor, i.e. the N-type nitride nanorods, was damaged at an upper surface thereof due to dry etching, thereby forming a polar or semi-polar face.

Referring to FIGS. 11 to 15, it can be seen that, as a result of wet etching the N-type nitride semiconductor nanorods using the KOH solution, the polar or semi-polar face, generated due to dry etching was removed. Further, referring to FIG. 15, it can be seen that, after wet etching for 15 min, the diameter of the nanorods decreased to about 300 nm. Further, it can also be seen that, as the wet etching time increased, the polar and semi-polar faces were removed, and low-diameter nanorods were formed.

In conclusion, it can be seen that, when wet etching is sequentially performed using a KOH solution after dry etching, c-axis grown nanorods, the polar and semi-polar faces of which are removed, are formed.

FIG. 16 is an SEM showing formation of a pyramid-shaped p-type semiconductor layer according to one embodiment of the present invention.

Referring to FIG. 16, p-GaN is intentionally partially combined into a P-type nitride semiconductor layer having a pyramid shape. Such a P-type nitride semiconductor layer has a wider surface area than in a P-type nitride semiconductor layer that is formed in a flat type, thereby improving light-extraction efficiency.

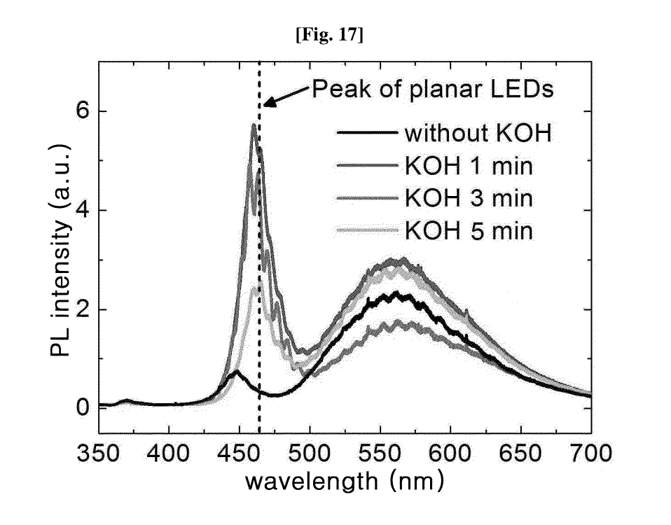

FIG. 17 is a graphical diagram showing optical properties of an LED according to one embodiment of the present invention.

Referring to FIG. 17, it can be seen that nanorods subjected only to dry etching (i.e., without KOH) has low PL intensity due to reduction in electrical optical characteristics resulting from surface damage by dry etching. Further, it can be seen that when the nanorods are subjected to wet etching using a KOH solution, the PL intensity increases and forms a similar peak to that of a flat panel LED.

With KOH wet etching, the nanorods have a gradually decreasing diameter, which causes reduction in PL intensity. More specifically, the reason why the intensity of PL increases as the diameter of the nanorods increases is because an increased diameter of the nanorods also causes an increase in sectional area that absorbs laser light (improved fill factor).

Although some exemplary embodiments have been described herein, it should be understood by those skilled in the art that these embodiments are given by way of illustration only, and that various modifications, variations and alterations can be made without departing from the spirit and scope of the invention. The scope of the present invention should be defined by the appended claims and equivalents thereof.

What is claimed is:

1. A nitride-based light emitting diode (LED) comprising:
an n-type nitride semiconductor layer formed on a substrate;
a plurality of n-type nitride semiconductor nanorods formed on the n-type nitride semiconductor layer and each having a non-polar face on a major surface thereof;
a photoactive layer formed on the n-type nitride semiconductor layer and surfaces of the n-type nitride semiconductor nanorods;
a p-type nitride semiconductor layer formed in a hexagonal pyramid shape on the photoactive layer;
a current spreading layer formed on the p-type nitride semiconductor layer;
an anode formed on the current spreading layer; and
a cathode formed on an exposed surface of the n-type nitride semiconductor layer.

2. The nitride-based LED according to claim 1, wherein the n-type nitride semiconductor layer has a diameter ranging from 200 nm to 2000 nm.

3. The nitride-based LED according to claim 1, wherein, the n-type nitride semiconductor layer, the p-type nitride semiconductor layer, or the photoactive layer comprises GaN.

4. The nitride-based LED according to claim 1, wherein the photoactive layer comprises a multi-quantum well structure depending upon indium content.

5. The nitride-based LED according to claim 1, wherein the n-type nitride semiconductor layer has the same chemical composition as that of the n-type nitride semiconductor nanorods.

6. A method of manufacturing a nitride-based light emitting diode (LED), comprising:
sequentially forming an n-type nitride semiconductor layer and a mask layer on a substrate;
patterning the mask layer to expose a portion of a surface of the n-type nitride semiconductor layer to form an n-type nitride semiconductor protruding from the n-type nitride semiconductor layer;
removing the mask layer;
forming a plurality of nanorods having a non-polar face by removing a semi-polar face of the protruded n-type nitride semiconductor layer;
forming a photoactive layer on the n-type nitride semiconductor layer and surfaces of the n-type nitride semiconductor nanorods;
forming a p-type nitride semiconductor layer, protruding in a hexagonal pyramid shape, on the photoactive layer through intentional partial combination;
forming a current spreading layer on the p-type nitride semiconductor layer;
forming an anode on the current spreading layer; and
forming a cathode on an exposed surface of the n-type nitride semiconductor layer.

7. The method according to claim 6, wherein the mask layer comprises at least one selected from the group consisting of a silicon oxide film and a silicon nitride film.

8. The method according to claim 6, wherein the nanorods are formed by wet etching using a KOH solution having a concentration from 2 M to 4 M.

9. The method according to claim 8, wherein the wet etching is performed at a temperature ranging from 80° C. to 120° C. for 3 minutes to 20 minutes.

10. The method according to claim 6, wherein the photoactive layer has a multi-quantum well structure depending upon indium content.
